(19) United States
(12) Patent Application Publication
(10) Pub. No.: US 2024/0175134 A1
(43) Pub. Date: May 30, 2024

(54) CONDUCTIVE COOLING OF A LOW TEMPERATURE PEDESTAL OPERATING IN A HIGH TEMPERATURE DEPOSITION SEQUENCE

(71) Applicant: LAM RESEARCH CORPORATION, Fremont, CA (US)

(72) Inventors: Gary B. LIND, Penn Vally, CA (US); Ravi VELLANKI, San Jose, CA (US); Jeff CLEVENGER, Morgan Hill, CA (US); Vinayakarddy GULABAL, Yadgir (IN)

(21) Appl. No.: 18/282,021

(22) PCT Filed: Mar. 21, 2022
(86) PCT No.: PCT/US2022/021078

§ 371 Date: Sep. 14, 2023

(30) Foreign Application Priority Data
Mar. 25, 2021 (IN) 202141012976

(51) Int. Cl. C23C 16/458; C23C 16/455; C23C 16/46

(52) U.S. Cl. CPC C23C 16/4586; C23C 16/45544; C23C 16/4585; C23C 16/463

(57) ABSTRACT

A pedestal comprises a base portion, a stem portion, and a heater arranged in the base portion. The stem portion has a first end attached to a center region of the base portion. The heater includes a first loop arranged in the center region of the base portion. A first perimeter of the first loop is less than or equal to a second perimeter of the first end of the stem portion.

### CROSS-REFERENCE TO RELATED APPLICATIONS

This application claims the benefit of Indian Provisional Application No. 202141012976, filed on Mar. 25, 2021. The entire disclosure of the application referenced above is incorporated herein by reference.

### FIELD

The present disclosure relates generally to substrate processing systems and more particularly to conductive cooling of a low temperature pedestal operating in a high temperature deposition sequence.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing tool typically includes a plurality of stations in which to perform deposition, etching, and other treatments on substrates such as semiconductor wafers. Examples of processes that may be performed on a substrate include, but are not limited to, a chemical vapor deposition (CVD) process, a chemically enhanced plasma vapor deposition (CEPVD) process, a plasma enhanced chemical vapor deposition (PECVD) process, a sputtering physical vapor deposition (PVD) process, atomic layer deposition (ALD), and plasma enhanced ALD (PEALD). Additional examples of processes that may be performed on a substrate include, but are not limited to, etching (e.g., chemical etching, plasma etching, reactive ion etching, etc.) and cleaning processes.

During processing, a substrate is arranged on a substrate support such as a pedestal in a station. During deposition, gas mixtures including one or more precursors are introduced into the station, and plasma may be optionally struck to activate chemical reactions. During etching, gas mixtures including etch gases are introduced into the station, and plasma may be optionally struck to activate chemical reactions. A computer-controlled robot typically transfers substrates from one station to another in a sequence in which the substrates are to be processed.

In ALD, a gaseous chemical process sequentially deposited a thin film on a surface of a material (e.g., a surface of a substrate such as a semiconductor wafer). Most ALD reactions use at least two chemicals called precursors (reactants) that react with the surface of the material one precursor at a time in a sequential, self-limiting manner. Through repeated exposure to separate precursors, a thin film is gradually deposited on the surface of the material. Thermal ALD (T-ALD) is carried out in a heated station. The station is maintained at a sub-atmospheric pressure using a vacuum pump and a controlled flow of an inert gas. The substrate to be coated with an ALD film is placed in the station and is allowed to equilibrate with the temperature of the station before starting the ALD process.

### SUMMARY

A pedestal comprises a base portion, a stem portion, and a heater arranged in the base portion. The stem portion has a first end attached to a center region of the base portion. The heater includes a first loop arranged in the center region of the base portion. A first perimeter of the first loop is less than or equal to a second perimeter of the first end of the stem portion.

In other features, the stem portion includes a conical portion and a cylindrical portion. The conical portion has the first end attached to the base portion and a second end having a smaller diameter than the first end. The cylindrical portion has the smaller diameter and extending from the second end of the conical portion.

In other features, the stem portion includes a first portion and a second portion. The first portion has the first end attached to the base portion and a second end having a smaller cross-sectional area than the first end. The second portion has the smaller cross-sectional area and extending from the second end of the first portion.

In another feature, the stem portion includes a wall having a thickness between 0.25 and 0.35 inches.

In another feature, the heater includes a second loop that surrounds the first loop and has a third perimeter that is greater than the second perimeter of the first end of the stem portion.

In another feature, the heater includes a second loop that is concentric with the first loop and has a greater circumference than the second perimeter of the first end of the stem portion.

In another feature, the heater includes a second loop that is concentric with the first loop and has a diameter three times larger than the first loop.

In another feature, the heater includes a second loop that is concentric with the first loop and has a diameter that is four-fifth of an outer diameter of the pedestal.

In another feature, an angle of descent of the conical portion from the first end is between 25 and 30 degrees relative to a height of the stem portion.

In another feature, a first height of the conical portion is one-third of a second height of the stem portion.

In another feature, the stem portion is monolithic.

In another feature, the stem portion is Y-shaped.

In another feature, the stem portion is cylindrical.

In another feature, the first portion is cup shaped.

In another feature, the first portion has a shape of a polygon.

In another feature, the pedestal further comprises a cooling assembly mounted to the stem portion.

In another feature, the pedestal further comprises a lift assembly attached to the cooling assembly to move the pedestal along a height of the stem portion.

In still other features, a pedestal comprises a base portion and a stem portion. The base portion includes a heater having a first loop arranged at a center region of the base portion and including a second loop that surrounds the first loop. The stem portion has a first end attached to the center region of the base portion. A first perimeter of the first loop of the heater is less than or equal to a second perimeter of the first end of the stem portion. A third perimeter of the second loop is greater than the second perimeter of the first end of the stem portion and less than a fourth perimeter of the base portion.

In another feature, the stem portion includes a wall having a thickness between 0.25 and 0.35 inches.

In another feature, the pedestal further comprises a cooling assembly mounted to a second end of the stem portion.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 schematically shows an example of a substrate processing tool comprising multiple stations for processing substrates;

FIG. 2 shows an example of a substrate processing system comprising a station configured to process a substrate;

FIG. 3 shows an example of a ring assembly used to transport a substrate between stations in the substrate processing tool of FIG. 1;

FIG. 4 shows a side cross-sectional view of an example of a pedestal without a tapered stem;

FIG. 5 shows a side cross-sectional view of an example of a pedestal with a tapered stem;

FIG. 6 shows a plan view of an example of a heater used in the pedestal of FIG. 4;

FIG. 7 shows a plan view of an example of a heater used in the pedestal of FIG. 5; and

FIG. 8 schematically shows an example of a mounting assembly used to mount a stem portion of a pedestal to a pedestal lift assembly.

In the drawings, reference numbers may be reused to identify similar and/or identical elements.

### DETAILED DESCRIPTION

In some substrate processing tools comprising multiple stations, a substrate and a ring assembly are cycled through the stations together as a unit. In some processes, one of the stations (hereinafter a first station) operates at a lower temperature than the other stations. When the ring assembly is transferred from a hotter station to a cooler station (i.e., the first station), a relatively large amount of heat is transferred by the ring assembly to the cooler station. Typically, a mounting assembly, which is mounted on a stem portion of a pedestal and is attached to a pedestal lift assembly, is cooled (e.g., using a coolant, convection cooling, or other methods) to pull as much heat from the pedestal as possible. Alternatively or additionally, various settings of a Proportional-Integral-Derivative (PID) controller, which is used to control a heater in a pedestal, can be altered to reduce the heating due to under- and over-shoot of the control.

However, for some processes, these techniques allow a temperature set point of the first station to be approximately 220° C. contrary to a desired set point of about 170° ° C. with other stations operating at about 445° C., for example. Standard pedestals for these processes are designed for a temperature set point of about 445° C., for example. These pedestals have a heater and a stem designed to accommodate greater surface losses to the station and to minimize stem thermal losses. At lower temperatures, however, while the surface losses decrease nonlinearly, the stem losses decrease linearly, which causes the standard pedestals to have a relatively cold center region.

To lower the temperature set point of the first station to approximately 150° C. and to prevent the center regions of the pedestals from becoming relatively cold, the present disclosure provides a new heater design for the pedestals and provides a mounting stem for the pedestals with an altered thermal conductivity and a different cross-section. Specifically, the mounting stem has an increased wall thickness and a flared (also called tapered) Y-shaped profile at the top end that attaches to the base portion of the pedestal. The new heater design includes an inner loop located within a circular region at the center of the pedestal, where the circumference of the circle passes through the two prongs of the Y-shaped profile of the stem. The new heater design and the increased thickness and cross-section of the stem allow the first station to maintain its pedestal at a desired temperature (e.g., about 150° C.) while the pedestals in the other stations operate at a relatively higher temperature.

As described below in detail, the new heater design distributes the heat to provide a more uniform radial temperature across the pedestal by positioning a portion (an inner loop) of the heater within an attachment radius of the pedestal stem. The new heater has inner and outer loops having diameters such that the heater provides relatively less heat at the OD of the pedestal and relatively more heat at the center of the pedestal. The stem is flared at the top end to allow a more uniform distribution of the heat removed by conduction through the stem as compared to a non-flared stem, which removes heat mostly from the center of the pedestal. For example, the flared top portion of the stem is generally Y-shaped, which allows the inner loop of the heater to be placed within the attachment radius of the stem and allows heat to be applied inside of the stem conduction zone for better thermal uniformity. The thicker stem wall provides increased thermal conductivity to the cooled mounting assembly mounted at the base of the stem. These features allow control at a lower temperature set point by maintaining a minimal heater duty cycle to provide accurate temperature set points with closed loop control. The heater portion positioned within the radius of the tapered stem and the thicker walled stem result in a pedestal that can provide uniform temperatures at a low set point while functioning with other pedestals that operate at much higher set points. These and other features of the present disclosure are described below in further detail.

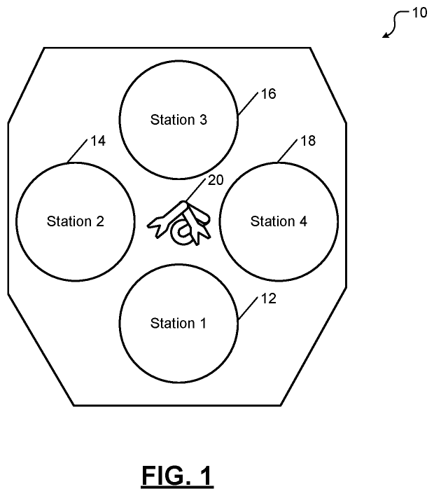

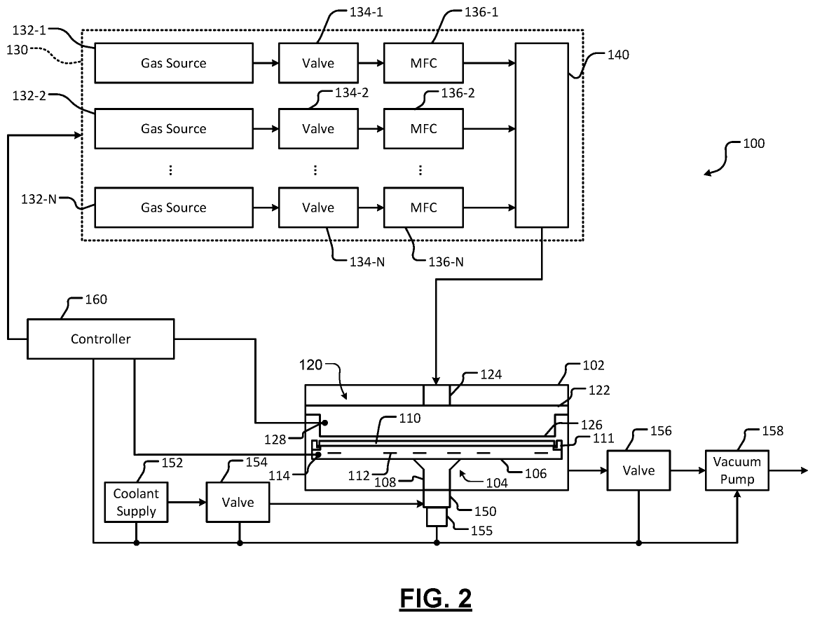

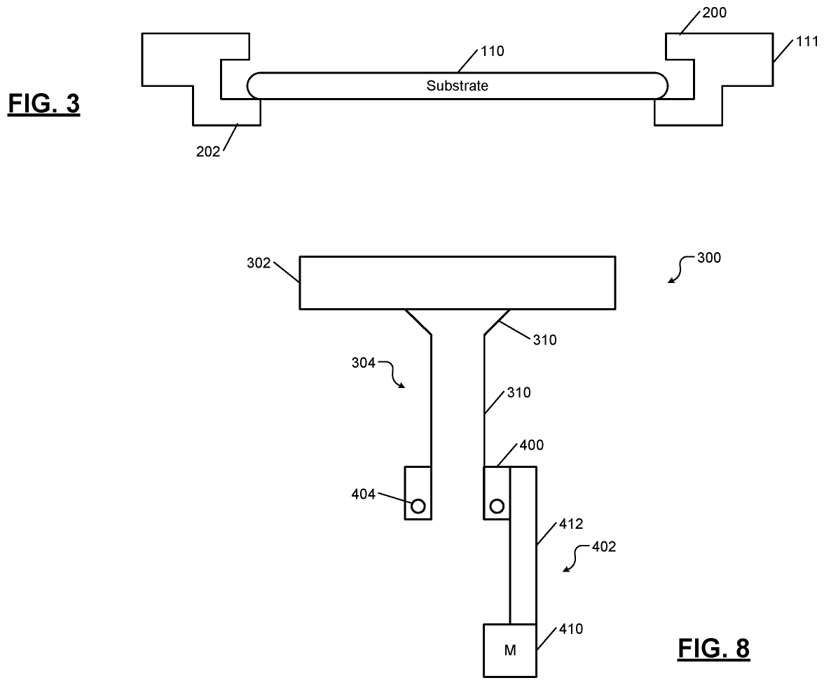

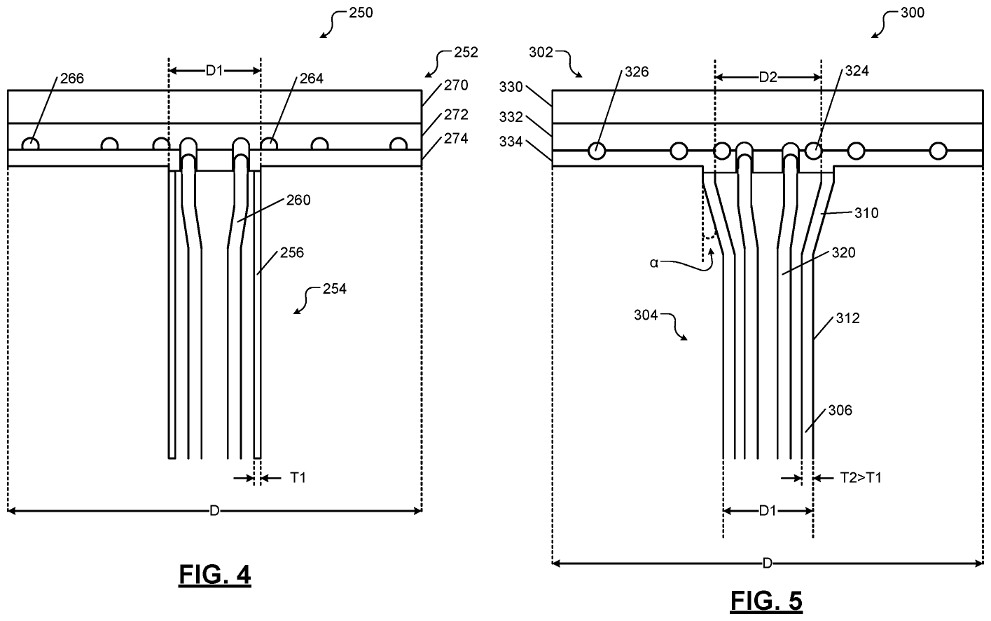

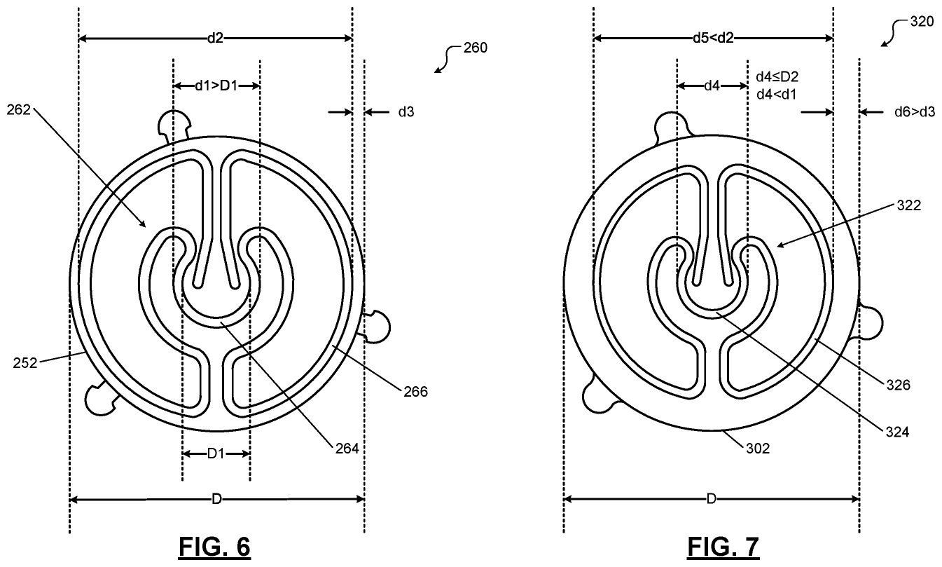

The present disclosure is organized as follows. Initially, to provide context, an example of a substrate processing tool comprising multiple stations is shown and described with reference to FIG. 1; and an example of a substrate processing system comprising a station configured to process a substrate is shown and described with reference to FIG. 2. An example of a ring assembly used to transport a substrate between stations in the substrate processing tool is shown and described with reference to FIG. 3. Examples of a standard pedestal and heater are shown and described with reference to FIGS. 4 and 6. Examples of a pedestal and heater designed according to the present disclosure are shown and described with reference to FIGS. 5 and 7. For completeness, an example of a mounting assembly used to mount a stem portion of a pedestal to a pedestal lift assembly is shown and described with reference to FIG. 8.

FIG. 1 schematically shows an example of a substrate processing tool 10. For example only, the substrate processing tool 10 includes four (or any number of) stations: a first station 12, a second station 14, a third station 16, and a fourth station 18. For example, each of the stations 12, 14, 16, and 18 may be configured to perform one or more respective processes on a substrate. A transfer robot 20 transfers the substrate from the first station 12 to the second station 14, from the second station 14 to the third station 16, and from the third station 16 to the fourth station 18 for processing. After the substrate is processed in the fourth station 18, the transfer robot 20 transfers the substrate to the first station 12. The substrate is removed from the first station 12 and a new substrate is loaded into the first station 12, and the above cycle is repeated.

A substrate is typically transferred from one station to another along with a ring assembly (shown in FIG. 3). The transfer robot 20 transfers the substrate and the ring assembly as a unit from one station to another. The ring assembly is annular and includes at least three fingers that extend vertically downward from an annular portion of the ring assembly and then extend radially inward. The substrate rests on the fingers during transfer. When the ring assembly and the substrate are lowered on a pedestal in a station, the substrate rests on the pedestal, and the ring assembly rests on the pedestal such that the fingers do not contact the substrate.

In some processes performed on the substrate in the substrate processing tool 10, the pedestal in the first station 12 has a lower temperature set point than the pedestals in the other three stations 14, 16, and 18. For example, the temperature set point of the pedestal in the first station 12 may be about 150° C. while the temperature set point of the pedestals in the other three stations 14, 16, and 18 may be about 450° C. The ring assembly is made of a ceramic material and absorbs heat from the pedestals during substrate processing. Accordingly, when the substrate and the ring assembly are transferred from the fourth station 18 to the first station 12, the ring assembly is much hotter than the temperature set point of the pedestal in the first station 12. Consequently, the ring assembly transfers a relatively large amount of heat to the pedestal in the first station 12. The heat transferred by the ring assembly to the pedestal increases the temperature of the pedestal above its desired temperature set point, even when the heater in pedestal is turned off.

A cooled mounting assembly (shown in FIGS. 2 and 8) mounted to the stem of the pedestals is used to pull (i.e., draw) heat from the pedestals. However, the amount of heat pulled by the cooled mounting assembly is limited by the thermal conductivity of the stem of the pedestal. The thermal conductivity of the stem, in turn, depends on the thickness of the stem wall. The present disclosure provides a stem design that includes a thick wall (examples of approximate dimensions are provided below). Additionally, an upper portion of the stem that attaches to the base portion of the pedestal is flared (i.e., the upper portion of the stem extends radially outward) and tapers downwards like a funnel. In general, the upper portion of the stem has a shape of the letter Y (see FIG. 5). The Y-shaped stem allows a more uniform distribution of the heat removed by conduction through the thick stem wall.

Additionally, to prevent the center region of the pedestal from becoming cold, the present disclosure provides a heater with an inner loop arranged in a circular region of the pedestal that lies between the two prongs of the letter Y (see FIGS. 5 and 7). That is, the inner loop of the heater lies in a circle having a circumference that lies on or intersects the two prongs of the Y-shaped stem. The diameter of the circle in which the inner loop of the heater lies is less than or equal to the distance between the two prongs of the Y-shaped stem. Accordingly, the cross-sectional area of the top end of the stem circumscribes the inner loop of the heater. The thick stem wall, the Y-shaped stem, and the heater with the inner loop arranged within the cross-sectional area of the Y-shaped stem provide uniform temperatures in pedestals with lower temperature set points while operating with other pedestals that are at much higher set points.

FIG. 2 shows an example of a substrate processing system 100 comprising a station 102 configured to process a substrate using a process such as thermal atomic layer deposition (T-ALD) or chemical vapor deposition (CVD). For example, the station 102 can be used as any of the stations 12, 14, 16, and 18 of the substrate processing tool 10 shown in FIG. 1.

The station 102 comprises a substrate support (e.g., a pedestal) 104. The pedestal 104 comprises a base portion 106 and a stem portion 108. During processing, a substrate 110 and a ring assembly 111 are arranged on the base portion 106 of the pedestal 104, and the substrate 110 is clamped to the base portion 106 of the pedestal 104 using vacuum clamping (not shown). The stem portion 108 is generally Y-shaped. A heater 112 is disposed in the base portion 106 to heat the substrate 110 during processing. The Y-shaped stem portion 108 and the heater 112 are shown and described below in further detail with reference to FIGS. 5 and 7. One or more temperature sensors 114 are disposed in the base portion 106 to sense the temperature of the pedestal 104.

The station 102 comprises a gas distribution device 120 such as a showerhead to introduce and distribute process gases into the station 102. The gas distribution device (hereinafter showerhead) 120 is made of a metal such as aluminum or an alloy. The showerhead 120 may include a base portion 122 and a stem portion 124. The stem portion 124 includes one end connected to a top plate of the station 102. The base portion 122 is generally cylindrical and extends radially outwardly from an opposite end of the stem portion 124 at a location that is spaced from the top plate of the station 102. A substrate-facing surface of the base portion 122 includes a faceplate 126. The faceplate 126 comprises a plurality of outlets or features (e.g., slots or through holes) through which process gases flow into the station 102. While not shown, the showerhead 120 may also comprise a heater. Further, the showerhead 120 may also comprises one or more temperature sensors 128 to sense the temperature of the showerhead 120.

A gas delivery system 130 comprises one or more gas sources 132-1, 132-2, . . . , and 132-N (collectively, the gas sources 132), where N is a positive integer. The gas sources 132 are connected by valves 134-1, 134-2, . . . , and 134-N (collectively, the valves 134) and mass flow controllers 136-1, 136-2, . . . , and 136-N (collectively, the mass flow controllers 136) to a manifold 140. An output of the manifold 140 is fed to the station 102. The gas sources 132 may supply process gases, cleaning gases, purge gases, inert gases, and so on to the station 102.

A cooling assembly 150 (shown in further detail in FIG. 8) is mounted at the base of the stem portion 108 of the pedestal 104. A coolant supply 152 supplies a coolant (e.g., water) to the cooling assembly 150 through a valve 154. The coolant flowing through the cooling assembly 150 draws heat from the stem portion 108 of the pedestal 104 as explained below in further detail with reference to FIG. 8. A pedestal lift assembly 155, which is also shown and described in further detail with reference to FIG. 8, is attached to cooling assembly 150. The pedestal lift assembly 155 moves the pedestal 104 vertically up and down relative to the showerhead 120.

A controller 160 controls the components of the substrate processing system 100. The controller 160 is connected to the heater 112 in the pedestal 104, the heater in the showerhead 120, and the temperature sensors 114 and 128 in the pedestal 104 and the showerhead 120. The controller 160 controls the power supplied to the heater 112 to control the temperature of the pedestal 104 and the substrate 110. The controller 160 may also control power supplied to the heater disposed in the showerhead 120 to control the temperature of the showerhead 120. The controller 160 controls the supply of the coolant to the cooling assembly 150 by controlling the coolant supply 152 and the valve 154 as described in further detail with reference to FIG. 8. The controller 160 controls the pedestal lift assembly 155 to control a gap between the pedestal 104 (and the substrate 110) and the showerhead 120.

A vacuum pump 158 maintains sub-atmospheric pressure inside the station 102 during substrate processing. A valve 156 is connected to an exhaust port of the station 102. The valve 156 and the vacuum pump 158 are used to control pressure in the station 102 and to evacuate reactants from the station 102 via the valve 156. The controller 160 controls the vacuum pump 158 and the valve 156.

FIG. 3 shows an example of the ring assembly 111. FIG. 3 shows a side cross-sectional view of the ring assembly 111 and the substrate 110. The ring assembly 111 includes an annular portion 200 and a plurality of fingers 202. The fingers 202 extend vertically downwards from the annular portion 200 and then extend radially inward. When the substrate 110 is transferred from one station to another in the substrate processing tool 10 shown in FIG. 1, the substrate 110 rests on the fingers 202 of the ring assembly 111. When the ring assembly 111 and the substrate 110 are lowered on the pedestal 104 in the station 102, the substrate 110 rests on the pedestal 104, and the ring assembly 111 rests on the pedestal 104 such that the fingers 202 do not contact the substrate 110 during processing.

FIGS. 4-7 show two examples of pedestals—one without a flared stem (FIG. 4) and another with the flared stem (FIG. 5)—and respective heaters. Non-limiting examples of dimensions of various features such as diameters and thicknesses of elements described below are provided after describing FIGS. 4-7 so as to not interrupt the flow of description of the various features.

FIG. 4 shows a side cross-sectional view of a pedestal 250 without a tapered stem. The pedestal 250 includes a base portion 252 and a stem portion 254. The base portion 252 comprises at least three metal plates 270, 272, 274 that are brazed or diffusion bonded together. While not shown, the metal plate 270 includes features for vacuum clamping a substrate (e.g., the substrate 110 shown in FIG. 2). The stem portion 254 is cylindrical, metallic, and attaches to the base portion 252 (to the metal plate 274) at a right angle. The stem portion 254 includes a cylindrical wall 256. The wall 256 has a thickness T1. The stem portion 254 has a diameter D1. A heater 260 is disposed in the base portion 252 between the metal plates 272 and 274. For example, the heater 260 includes an electrically insulated resistive element. The controller 160 (shown in FIG. 2) controls the power supplied to the heater 260. As shown in FIG. 6, the heater 260 includes an inner loop (element 264 shown in FIG. 6) that lies outside the diameter D1 of the stem portion 254.

FIG. 5 shows a side cross-sectional view of a pedestal 300 with a flared or tapered stem. For example, the pedestal 300 may be used in the station 102 shown in FIG. 2 and in the stations 12, 14, 16, and 18 of the substrate processing tool 10 shown in FIG. 1. The pedestal 300 includes a base portion 302 and a stem portion 304. The base portion 302 comprises at least three metal plates 330, 332, 334 that are brazed or diffusion bonded together. While not shown, the metal plate 330 includes features for vacuum clamping a substrate (e.g., the substrate 110 shown in FIG. 2).

The stem portion 304 is metallic and generally Y-shaped. For example, the stem portion 304 includes a first conical portion 310 (an upper portion) and a second cylindrical portion 312 (a lower portion). The conical portion 310 has a first diameter at a first end that is attached to the base portion 304 (to the metal plate 334). The conical portion 310 has a second diameter at a second end that is attached to the cylindrical portion 312 having the second diameter, which is less than the first diameter.

The stem portion 304 (i.e., the conical portion 310 and the cylindrical portion 312) includes a wall 306. The wall 306 has a thickness T2 that is greater than T1. A heater 320 is disposed in the base portion 302 (between the metal plates 332 and 334). For example, the heater 320 includes an electrically insulated resistive element. The controller 160 (shown in FIG. 2) controls the power supplied to the heater 320. As shown in FIG. 7, the heater 320 has an inner loop (element 324 shown in FIG. 7) that lies inside the first diameter (D2) of the conical portion 310.

The upper portion of the stem portion 304 need not be conical in shape and can be of any other shape. For example, the upper portion of the stem portion 304 can also be cylindrical with a diameter greater than the lower cylindrical portion 312. Non-limiting examples of the other shapes include a cup shape, a polygonal shape, and so on. Further, while the wall of the conical portion 310 is shown tapering at an angle (a), the wall may be curved instead. In general, the upper portion of the stem portion 304 gradually extends radially outward from a bottom end that attaches to the cylindrical portion 312 to a top end that attaches to the base portion 302 of the pedestal 300. Regardless of the shape, the cross-sectional area of the upper end of the stem portion 304 that attaches to the base portion 302 circumscribes the inner loop (element 324 shown in FIG. 7) of the heater 320.

Further, the stem portion 304 can be of a single shape instead of the upper and lower portions of the stem portion 304 being of different shapes. Non-limiting examples of the single shape of the stem portion 304 include a cylindrical shape, a polygonal shape, and so on. Regardless of the shape, the cross-sectional area of the single shape of the stem portion 304 circumscribes the inner loop (element 324 shown in FIG. 7) of the heater 320.

Furthermore, in some examples, the stem portion 304 may be monolithic. That is, the conical portion 310 and the cylindrical portion 312 may be a single element. Alternatively, the conical portion 310 and the cylindrical portion 312 of the stem portion 304 may be separate elements.

FIG. 6 shows a plan view of the heater 260 used in the pedestal 250. The heater 260 includes a coil 262 that is distributed throughout the base portion 252 of the pedestal 250 as shown. For example, the heater 260 includes an inner loop 264 having a diameter d1 and an outer loop 266 having a diameter d2. The diameter d1 of the inner loop 264 is greater than the diameter D1 of the stem portion 254 of the pedestal 250. The diameter d2 of the outer loop 266 is such that the outer loop 266 extends nearly to an outer diameter D of the base portion 252 of the pedestal 250. The difference between the diameter d2 of the outer loop 266 and the outer diameter D of the base portion 252 of the pedestal 250 is d3. Examples of dimensions of these diameters are provided below.

FIG. 7 shows a plan view of the heater 320 used in the pedestal 300. The heater 320 includes a coil 322 that is distributed throughout the base portion 302 of the pedestal 300 as shown. For example, the heater 320 includes an inner loop 324 having a diameter d4 and an outer loop 326 having a diameter d5. The diameter d4 of the inner loop 324 is less than or equal to the diameter D2 of the upper conical portion 310 of the stem portion 302 of the pedestal 300. The diameter d4 of the inner loop 324 is also less than the diameter d1 of the inner loop 264 of the heater 260 used in the pedestal 250. Stated generally, regardless of the shape of the upper portion of the stem portion 304, a perimeter (or cross-sectional area) of the inner loop 324 is less than or equal to a perimeter (or cross-sectional area) of the upper end of the stem portion 304 that attaches to the base portion 302.

The diameter d5 of the outer loop 326 is such that the outer loop 326 does not extend close to the outer diameter D of the base portion 302 of the pedestal 300. The diameter d5 of the outer loop 326 is less than the diameter d2 of the outer loop 266 of the heater 260 used in the pedestal 250. The difference between the diameter d5 of the outer loop 326 and the outer diameter D of the base portion 302 of the pedestal 300 is d6, which is greater than d3.

The following are non-limiting examples of dimensions of the various diameters and thicknesses described above. For example, the outer diameter D of the pedestals 250 and 300 can be 14 inches. The following examples of the other dimensions are provided using D=14 inches as a reference. For example, the thickness T1 of the wall 256 of the stem portion 254 of the pedestal 250 can be T1=0.09 to 0.1 inch. For example, the thickness T2 of the wall 306 of the stem portion 304 of the pedestal 300 can be T2=0.25 to 0.35 inch.

For example, the diameter D1 of the stem portion 254 of the pedestal 250, which is also the diameter of the cylindrical portion 312 of the stem portion 304 of the pedestal 300 and the diameter of the lower end of the conical portion 310 of the stem portion 304, can be D1=3 inches. For example, the diameter D2 of the upper end of the conical portion 310 of the stem portion 304 can be D2=4.0 to 4.5 inches. Accordingly, a ratio of the diameter D2 of the upper end of the conical portion 310 to the diameter D1 of the lower end of the conical portion 310 may be about 4:3.

Stated generally, regardless of the shape of the upper portion of the stem portion 304 (i.e., conical, cup shaped, etc.), a ratio of the cross-sectional area of the upper end of the upper portion of the stem portion 304 to the cross-sectional area of the lower end of the upper portion of the stem portion 304 may be about 4:3. Further, for example, the angle α of descent of the conical portion 310 from the upper end that attaches to the base portion 302 to the lower end that attaches to the cylindrical portion 312 can be about 25-30 degrees relative to a vertical axis (i.e., a height) of the stem portion 304.

If the upper portion of the stem portion 304 of the pedestal 300 is polygonal, the area of cross-section of the upper portion of the stem portion 304 that is attached to the base portion 302 is sufficient to circumscribe the inner loop 324 of the heater 320. If the stem portion 304 of the pedestal 300 is a single cylindrical element, the diameter of the single cylindrical element may be D2=4.0 to 4.5 inches. If the stem portion 304 of the pedestal 300 is a single polygonal element, the cross-sectional area of the stem portion 304 is sufficient to circumscribe the inner loop 324 of the heater 320.

Further, for example, the diameter d4 of the inner loop 324 of the heater 320 is less than or equal to the diameter D2 of the upper end of the conical portion 310, where D2=4.0 to 4.5 inches; and the diameter d5 of the outer loop 326 of the heater 320 may be about 11 inches. Accordingly, a ratio of the diameter d4 of the inner loop 324 to the diameter d5 of the outer loop 326 of the heater 320 may be about 1:3.

Additionally, for example, the height (or length) of the stem portion 304 may be about 7 inches, and the height of the upper portion of the step portion 304 may be about 2.5 to 3 inches. Accordingly, for example, the height of the upper portion of the stem portion 304 may be approximately one-third the height of the stem portion 304. Furthermore, for example, the diameter d2 of the outer loop 266 of the heater 260 may be about 12.5 inches; and the diameter d5 of the outer loop 326 of the heater 320 may be about 11 inches. Accordingly, for example, the distance d3 between the outer loop 266 of the heater 260 and the outer diameter D of the pedestal 250 may be approximately (14−12.5)=1.5 inches, and the distance d6 between the outer loop 326 of the heater 320 and the outer diameter D of the pedestal 300 may be about (14−11)=3 inches. Further, for example, the diameter d5 of the outer loop 326 of the heater 320 may be approximately ⅘^{th} or 80% of the outer diameter D of the pedestal 300.

FIG. 8 schematically shows an example of a mounting assembly 400 used to mount the stem portion 304 of the pedestal 300 to a pedestal lift assembly 402. The mounting assembly 400 (shown as element 150 in FIG. 2) is mounted to the base of the cylindrical portion 312 of the stem portion 304. For example, the mounting assembly 400 may comprise one or more clamps (not shown). In addition, the mounting assembly 400 includes a tube or conduit 404 through which a coolant (e.g., water) can be circulated. Alternatively, while not shown, other cooling arrangements such as convective cooling may be used. The coolant flowing through the mounting assembly 400 draws heat from the stem portion 304 of the pedestal 300. Accordingly, the mounting assembly 400 may also be called a cooling assembly.

Specifically, the conduit 404 in mounting assembly 400 receives the coolant from the coolant supply 152 via the valve 154 (shown in FIG. 2). The coolant flow through the conduit 404 is controlled by the controller 160 (also shown in FIG. 2). For example, the controller 160 can control the flow rate and/or the temperature of the coolant flowing through the conduit 404 based on the temperature of the pedestal 300. By controlling the flow rate and/or the temperature of the coolant flowing through the conduit 404, the amount of heat drawn by the coolant from the pedestal 300 by conduction through the stem portion 304 can be controlled. The thick wall 306 and the Y-shape of the stem portion 304 allow a more uniform distribution of the heat removed by conduction through the stem portion 304.

The pedestal lift assembly 402 is attached to the mounting assembly 400. The pedestal lift assembly 402 (shown as element 156 in FIG. 2) moves the pedestal 300 along the vertical axis that is perpendicular to the plane in which the base portion 302 of the pedestal 300 lies. For example, the pedestal lift assembly 402 comprises a stepper motor 410 and a ball screw drive 412 that includes a ball screw and a linear bearing (not shown). The controller 160 controls the stepper motor 410 to move the pedestal 300 vertically up and down relative to the showerhead 120 (shown in FIG. 2).

The mounting assembly 400 provides cooling independently of the pedestal lift assembly 402. That is, the pedestal lift assembly 402 is unnecessary for the cooling provided by the mounting assembly 400. Rather, by adding the conduit 404 to the mounting assembly 400, which is typically used with the pedestal lift assembly 402, the mounting assembly 400 is used to serve the additional purpose of providing cooling as described above.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A pedestal comprising:
a base portion;
a stem portion having a first end attached to a center region of the base portion; and
a heater arranged in the base portion, the heater including a first loop arranged in the center region of the base portion, wherein a first perimeter of the first loop is less than or equal to a second perimeter of the first end of the stem portion.

2. The pedestal of claim 1 wherein the stem portion includes:
a conical portion having the first end attached to the base portion and a second end having a smaller diameter than the first end; and
a cylindrical portion having the smaller diameter and extending from the second end of the conical portion.

3. The pedestal of claim 1 wherein the stem portion includes:
a first portion having the first end attached to the base portion and a second end having a smaller cross-sectional area than the first end; and
a second portion having the smaller cross-sectional area and extending from the second end of the first portion.

4. The pedestal of claim 1 wherein the stem portion includes a wall having a thickness between 0.25 and 0.35 inches.

5. The pedestal of claim 1 wherein the heater includes a second loop that surrounds the first loop and has a third perimeter that is greater than the second perimeter of the first end of the stem portion.

6. The pedestal of claim 1 wherein the heater includes a second loop that is concentric with the first loop and has a greater circumference than the second perimeter of the first end of the stem portion.

7. The pedestal of claim 1 wherein the heater includes a second loop that is concentric with the first loop and has a diameter three times larger than the first loop.

8. The pedestal of claim 1 wherein the heater includes a second loop that is concentric with the first loop and has a diameter that is four-fifth of an outer diameter of the pedestal.

9. The pedestal of claim 2 wherein an angle of descent of the conical portion from the first end is between 25 and 30 degrees relative to a height of the stem portion.

10. The pedestal of claim 2 wherein a first height of the conical portion is one-third of a second height of the stem portion.

11. The pedestal of claim 2 wherein the stem portion is monolithic.

12. The pedestal of claim 1 wherein the stem portion is Y-shaped.

13. The pedestal of claim 1 wherein the stem portion is cylindrical.

14. The pedestal of claim 3 wherein the first portion is cup shaped.

15. The pedestal of claim 3 wherein the first portion has a shape of a polygon.

16. The pedestal of claim 1 further comprising a cooling assembly mounted to the stem portion.

17. The pedestal of claim 16 further comprising a lift assembly attached to the cooling assembly to move the pedestal along a height of the stem portion.

18. A pedestal comprising:
a base portion including a heater having a first loop arranged at a center region of the base portion and including a second loop that surrounds the first loop; and
a stem portion having a first end attached to the center region of the base portion;
wherein a first perimeter of the first loop of the heater is less than or equal to a second perimeter of the first end of the stem portion; and
wherein a third perimeter of the second loop is greater than the second perimeter of the first end of the stem portion and less than a fourth perimeter of the base portion.

19. The pedestal of claim 18 wherein the stem portion includes a wall having a thickness between 0.25 and 0.35 inches.

20. The pedestal of claim 19 further comprising a cooling assembly mounted to a second end of the stem portion.
